(19) United States
(12) Patent Application Publication
(10) Pub. No.: US 2026/0333645 A1
(43) Pub. Date: Oct. 22, 2026

(54) PUMP ARRAY ASSEMBLY FOR IMMERSION COOLING

(71) Applicant: HEWLETT PACKARD ENTERPRISE DEVELOPMENT LP, Spring, TX (US)

(72) Inventors: Austin Edward Rodriguez, The Woodlands, TX (US); Pranay Mahendra, Tomball, TX (US); Keith Allen Sauer, Spring, TX (US); Steven Dale Webster, Montgomery, TX (US)

(21) Appl. No.: 19/185,589

(22) Filed: Apr. 22, 2025

(51) Int. Cl. H05K 7/20

(52) U.S. Cl. CPC H05K 7/20836; H05K 7/20272; H05K 7/20281; H05K 7/20781

(57) ABSTRACT

An information processing system comprises a system board having electronic components and supported by a chassis. The chassis includes fan cage attachment points configured to receive a fan cage. A pump array assembly comprises a mounting cage configured to couple to the chassis. One or more pumps, each comprising an intake and an outlet, are coupled to the mounting cage. When the information processing system is immersed in a pool of liquid coolant in an immersion cooling tank, the pumps draw a flow of the liquid coolant from the pool through the intake and eject the flow through the outlet back into the pool as at least one output stream directed over at least one of the electronic components.

Information processing systems, (e.g., servers) generate heat during operation and, if the heat is not dissipated or cooling is not provided, damage can occur to various components within the system. One way to provide cooling to a system is through the use of airflow through the system, such as by using fans disposed within the system, with airflow over components providing cooling. Another way to provide cooling to a system is through the use of liquid cooling, where coolant liquids flowing over components remove heat from the system.

### BRIEF DESCRIPTION OF THE DRAWINGS

The present disclosure can be understood from the following detailed description, either alone or together with the accompanying drawings. The drawings and related description of the figures are included to provide a further understanding of the present disclosure and are incorporated in and constitute a part of this specification. The drawings illustrate one or more nonlimiting aspects and implementations of the present teachings and together with the description explain certain principles and operation. In the drawings:

FIG. 1 is a block diagram of a system including a pump array assembly for immersion cooling.

FIG. 2 is a perspective view of a mounting cage for a pump array assembly for immersion cooling.

FIG. 3 is a rear elevation view of the mounting cage of FIG. 2.

FIG. 4 is a bottom elevation view of the mounting cage of FIG. 2.

FIG. 5 is a top elevation view of the mounting cage of FIG. 2.

FIG. 6 is a perspective view of a pump array assembly including the mounting cage of FIG. 2 and two pumps shown in in a decoupled state during a pump installation process.

FIG. 7 is a perspective view of the pump array assembly of FIG. 6 with two pumps in an installed state on the mounting cage.

FIG. 8 is a front perspective view of the pump array assembly of FIG. 6 with six pumps installed on the mounting cage for immersion cooling.

FIG. 9 is a rear perspective view of the pump array assembly of FIG. 8.

FIG. 10 is a rear perspective view of the pump array assembly of FIG. 8 with an intake manifold.

FIG. 11 is a rear perspective view of the pump array assembly of FIG. 8 with the intake manifold.

FIG. 12 is a rear elevation view of the intake manifold of FIG. 10.

FIG. 13 is a perspective view of an information processing system including a pump array assembly for immersion cooling.

FIG. 14 is another perspective view of the information processing system of FIG. 13.

FIG. 15 is a method for adapting an information processing system to include a pump array assembly for immersion cooling.

### DETAILED DESCRIPTION

Information processing components, such as CPUs, are increasing in power and heat generation, which is making it increasingly difficult to efficiently cool the system via airflow. As heat generation increases, greater volumes of air must be moved through the system to achieve the same level of cooling. The increase in air volume through the system results in increased power consumption and increased noise. In addition, as the amount of air to be moved through the system increases, costs for the various components, such as fans and heat sinks, also increase.

One alternative method for cooling an information processing system is liquid cooling, in which liquid coolant is used to remove heat from a system. One form of liquid cooling is direct liquid cooling (DLC), in which liquid coolant flows through a system using tubes/pips, and heat is extracted from heat generating components of the system into the liquid coolant via cold plates coupled to the components. DLC is often used in information processing systems having high component density, such as supercomputers or high-performance compute systems, where there are multiple components generating high amounts of heat. DLC is highly efficient at removing heat from a system, however, DLC has a high cost due to the addition of further components, such as cold plates and coolant pipes, to the system. Due to the complexity of many DLC cooled systems, these additional components are often customized for each particular system, meaning that many components cannot be easily reused.

Immersion cooling, on the other hand, involves submerging part or all of an information processing system in a tank of an electrically non-conductive liquid coolant, such as a dielectric liquid. This allows the liquid coolant to contact some or all of the information processing components, such that heat generated by the components can be discharged into the coolant. The heated coolant can then be circulated through a heat exchanger to remove the heat before being recirculated into the tank. Immersion cooling represents an efficient method of cooling a system without a corresponding increase in power or noise output, as may occur in an air-cooled system. Similarly, immersion cooling allows some of the benefits of direct liquid cooling, namely, the increase in heat able to be removed from the system thanks to the use of a coolant fluid, without requiring a custom designed cooling system based on the particular information processing system. As such, the increase in accessibility and affordability of immersion cooling systems make immersion cooling an attractive option for system cooling.

When designing a new information processing system, it is possible to design the system to be specifically cooled via immersion cooling. However, generating and validating such a new system design can be costly and difficult. Furthermore, such a special-purpose system may have a relatively limited market segment, i.e., it may be limited only to those who use immersion cooling. Accordingly, it may be preferable if an existing information processing system originally designed for use in some other context, such as for air cooling, could be used in an immersion cooling system, as this could save costs by avoiding the need for a new system design and also could allow the same general design to cover multiple market segments (i.e., both air cooling and immersion cooling).

However, existing information processing systems that were originally designed for air cooling may not be well optimized for immersion cooling. In general, an air-cooled system can be relatively easily converted to a state in which it can be used in an immersion cooling tank, for example by removing the air-cooling specific components, such as fans, heat sinks, and baffles, as well as by removing components incompatible with immersion, such as thermal pasts, stickers, or the like. This form of conversion may be referred to herein as a baseline conversion because it represents a minimal conversion to ready the system for immersion. While such baseline conversion can relatively easily allow for an air-cooled system to be converted for use in the immersion cooling tank, the resulting system is not well optimized for immersion cooling and thus some of the benefits which may be possible with immersion cooling may not be fully realized. For example, it may be desirable to provide additional cooling to certain components, such as a CPU, beyond the cooling that occurs when the system which has been converted in the manner described above is immersed in an immersion tank.

To address these and other issues, in examples disclosed herein, a pump array assembly is installed in an information processing system in a region between the system board and a front or rear panel of the system, with the pump array assembly arranged to generate flows of liquid coolant directed towards hot components of the device, such as CPUs and memory, to improve their cooling. The pump array assembly includes a mounting cage coupled to the chassis of the system and a number of pumps coupled to the mounting cage. The pump array assembly may be used in an information processing system which was originally designed for air cooling and which has been (or is being) converted into an immersion ready state and may further optimize the system for immersion cooling beyond the baseline conversion. Optimized, in this context, means that the system is configured to provide superior cooling performance to one or more components, such as the CPU, beyond that which would be provided by the system without the pump array assembly (i.e., beyond what would have been provided if only the baseline conversion were done). In some examples, the pump array assembly may be configured to leverage features of the chassis originally designed for air cooling. For example, the region in which the pump array assembly is installed may be the same region in which fans would be, or previously were, located in an air-cooled configuration of the system (hereinafter the “fan region”). For example, in some systems this fan region in which the pump array assembly is installed may be located in the space between a front edge of the system board and a front drive cage section of the chassis. Furthermore, in some examples, the mounting cage may couple to the chassis at mounting features for a fan cage. In addition, in some examples the pumps may be electrically coupled to and driven by fan power connectors—i.e., the connectors designed to provide power and driving signals to the fans in an air-cooled configuration of the system—which may be mounted on the system board or on a fan board coupled to the system board.

In some examples, the mounting cage comprises a base having multiple pump mounts formed thereon, with each pump mount comprising a space defined to receive one of the pumps and engagement features configured to hold the pump in the space. The base may extend along a width dimension of the chassis, in some cases fully across the width of the chassis, with the pump mounts being distributed along the base at various locations. Each of the pump mounts includes a space in which a pump can be disposed which is bounded by a set of brackets configured to engage with and hold the pump. In some examples, there are four brackets for each pump mount, with the brackets extending vertically from the base at locations corresponding to four corners of a rectangle, such that the brackets can engage different sides or edges of the pump to hold the pump between the brackets. In some examples, a pump housing of a pump may have a shape like a rectangular prism (i.e., a box) with four vertically extending edges, and the brackets may be arranged to engage with the four vertically oriented edges, respectively, of the pump housing. In some examples, the brackets hold the pump therebetween by a friction fit or snap fit and may retain a pump in an installed position in the mounting cage. Each pump may be oriented such that a fluid outlet faces at least one electronic component of the system, allowing liquid coolant to be directed over the electronic component by the pump.

At least some of the pumps may further be coupled to an intake manifold which is positioned remotely from the pumps and which draws in coolant from the immersion tank and provides the coolant to the pumps. The intake manifold may be positioned at a location which allows the pumps to access liquid which is cooler than the liquid in the immediate vicinity of the pumps. For instance, in some examples where liquid in the immersion tanks goes from cool at the front of the servers to warm at the rear of the servers, then the intake manifold may be located towards the front of the chassis, such as in the drive cage section of the chassis (e.g., the intake manifold may occupy one or more of the bays of a drive cage in the drive cage section, or may replace one of the drive cages entirely). Conversely, in some examples where liquid goes from cool at the rear to warm at the front, the intake manifold may be located near the rear panel, such as in an unused riser cage space. The intake manifold may serve to help funnel coolant liquid to the pumps, allowing the pumps to direct coolant liquid over desired electronic components on the system board. Outlets on the intake manifold may be coupled to the pumps at pump inlets via tubing such that coolant liquid can be moved through the tubes to the pumps. By using the intake manifold, the pumps receive coolant liquid that has not been heated due to contact with other electronic components. This allows the pumps to direct cooler liquid over the electronic components, which in turn allows the coolant liquid to receive and carry more heat away from the components, thus optimizing the cooling provided by the installed pumps.

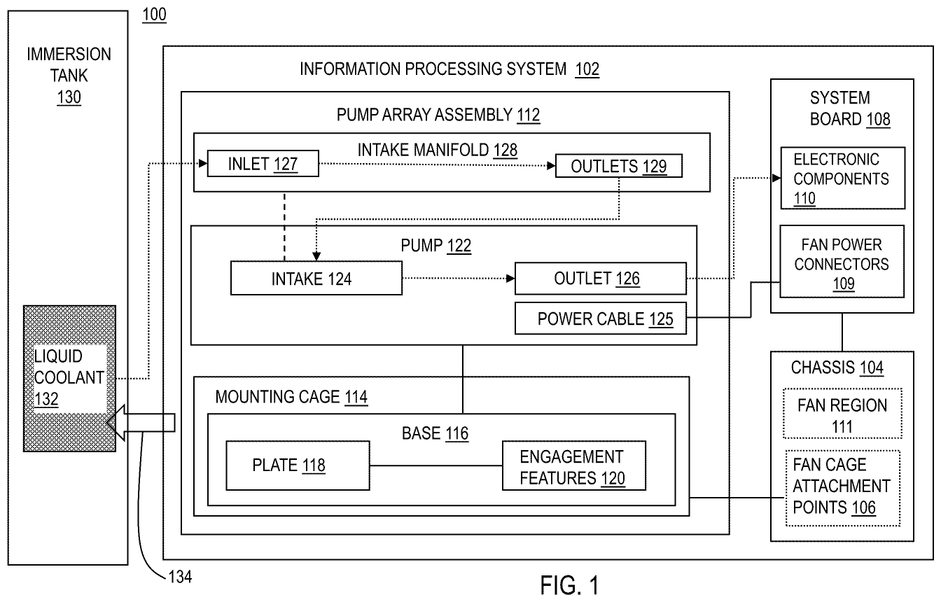

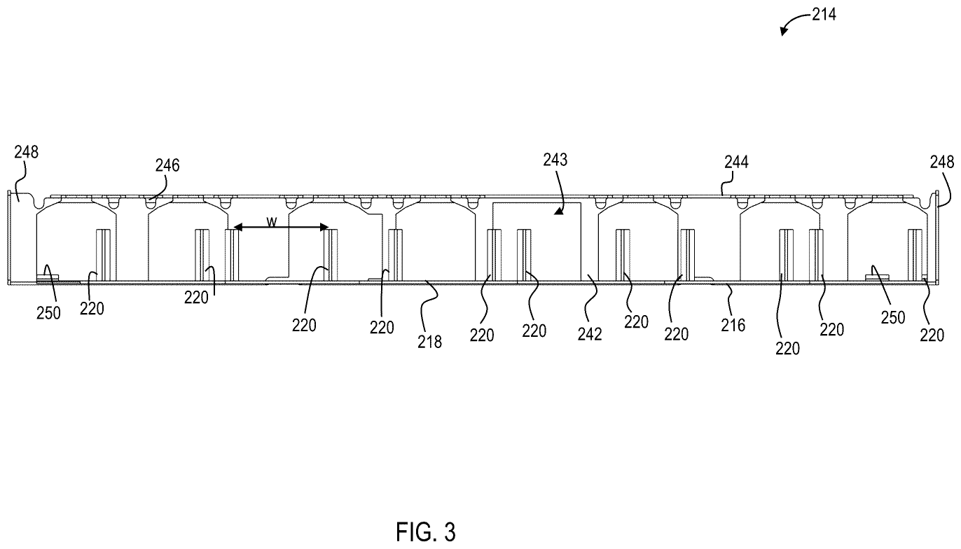

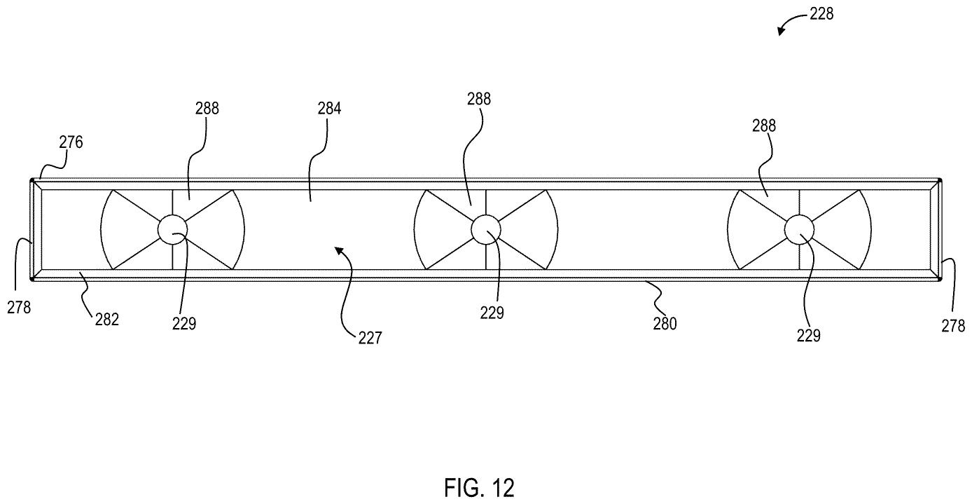

These and other examples will be described in greater detail below in relation to FIGS. 1-15.

FIG. 1 illustrates an example system 100. FIG. 1 is schematic in nature, and it should be understood that FIG. 1 is not intended to illustrate specific shapes, dimensions, positional relationships, or other structural details accurately or to scale, unless otherwise noted herein. Implementations of information processing system 100 may have different numbers and arrangements of the illustrated components. In addition, components illustrated in FIG. 1 may be omitted from some examples disclosed herein, and components which are not illustrated in FIG. 1 may also be included in some examples disclosed herein. In FIG. 1, physical connections (e.g. physical attachment and/or support) between components are indicated conceptually by solid lines extending between the components. Certain positional relationships are indicated by thick white-filled arrows. Motion of coolant is indicated by dotted-line arrows.

System 100 is a system for immersion cooling information processing devices, such as servers, networking devices, or the like. System 100 includes an information processing system 102 and an immersion tank 130. The immersion tank 130 contains a pool of liquid coolant 132 and is configured to receive multiple information processing systems immersed in that coolant 132 to provide immersion cooling thereto, as will be explained in greater detail below.

Information processing system 102 may be a server, a networking device (e.g., switch, router, etc.), or other device with information processing components. Information processing system 102 may include a chassis 104, a system board 108, and a pump array assembly 112.

Chassis 104 may include structural components to support and/or house other component of the system 102. The chassis 104 may, for example, include a housing or enclosure comprising walls or panels, such as a base, side walls, a cover coupled together to define an interior volume in which other components of the system are housed. The chassis may also include other support structures, which may be disposed in or form integral parts of the aforementioned housing, such as drive cages, power supply unit cages, etc. In lieu of forming an housing, chassis 104 may alternatively include a tray or other support structure which supports, but does not necessarily fully enclose, the components of the system.

In some examples, system 102 is compatible with both air-cooling and immersion cooling, meaning that the system 102 is switchable between an air-cooled configuration and an immersion cooled configuration. In such examples, chassis 104 may further include a fan region 111 and fan cage attachment points 106 (these are illustrated in FIG. 1 in dotted lines to indicate that they are not necessarily present in all examples of the system 102). Fan region 111 is a region in the chassis 104 configured to receive a set of fans in the air cooled configuration. For example, the fan region 111 may comprise an open space between the system board 108 and a drive cage at a front of the chassis 104. Fan cage attachment points 106 comprise attachment features configured to attach a fan cage, which holds the fans, to the chassis 104. In some examples, fan cage attachment points 106 may be disposed in or on side walls of chassis 104 and/or a base of the chassis 104. The system 102 may also include fan power connectors 109 to mate with fan power cables of the fans to supply power to the fans, and these connectors 109 may be, for example, mounted to the system board 108. When the system 102 is deployed in an immersion cooled configuration, the fans and fan cage may be removed. Therefore, in the immersion cooled configuration, if any fan region 111, fan cage attachment points 106, and/or fan power connectors 109 are included in the system 102, they are not used by the fans and instead may be used, in some examples, by the pump array assembly 112 described below.

A system board 108 may be supported by chassis 104. The system board 108 may be a motherboard that includes electronic components 110 coupled thereto, as well as fan power connectors 109, described above. Electronic components 110 include at least some information processing components, such as a central processing unit (CPU), a memory, or the like, as well as other passive or active electrical components (not illustrated), but examples are not so limited and any system board may be used.

A pump array assembly 112 may be coupled to chassis 104. Pump array assembly 112 may include a mounting cage 114 and an array of one or more pumps 122. In some examples, the pump array assembly 112 may also include an intake manifold 128.

In some examples in which the chassis 104 includes the fan region 111, the pump array assembly 112 is installed in the fan region 111 (in lieu of the fans, which are omitted or removed from the fan region 111). In some examples, in which the chassis 104 includes fan cage attachment points 106, the mounting cage 114 may be coupled to chassis 104 at the fan cage attachment points 106 in lieu of a fan cage (not shown) being coupled to the fan cage attachment points 106. Said differently, mounting cage 114 may be coupled to the chassis 104 by engaging corresponding attachment features on the mounting cage 114 with the fan cage attachment points 106. The mounting cage 114 may couple with the fan cage attachment points 106 by, for example, engagement of snap-fit connectors, a friction-fit connector, an actuatable latching mechanism, a mechanical fastener (e.g., screw), or another suitable connection.

Mounting cage 114 may include a base 116, which is configured to receive and hold the pump(s) 112. In some examples, the mounting cage 114 may couple with the chassis 104 at the base 116 of the mounting cage 114; that is, the base 116 may include attachment features to engage with and attach to the chassis 104. In some examples in which the mounting cage 114 attaches to fan cage attachment points 106, the corresponding attachment features which engage therewith may be located on the base 116 such that the base 116 engages with the fan cage attachment points 106. In other examples (described below), the corresponding attachment features which engage with the fan attachment points 106 may be part of another part of the mounting cage 114, such as a vertical wall (not illustrated) coupled to the base 116.

Base 116 may include a plate 118 and engagement features 120. Plate 118 may provide a generally planar surface to support the pump(s) 122 thereupon. When the mounting cage 114 is installed in the chassis 104, the plate 118 may be parallel to the base of the chassis 104, in some examples. A plurality of engagement features 120 are coupled to the plate 118, with the engagement features 120 being arranged in one or more groups. Each group of engagement features 120 may be configured to hold one of the pump(s) 122 in a particular location on the plate 118. More particularly, each group of engagement features 120 may be arranged on the plate 118 to define a space to receive one of the pump(s) 122 to engage with the pump 122 to hold and secure it to the mounting cage 114. The space may be an empty volume which is bounded in part, or otherwise defined by, by the engagement features 120. Each individual group of engagement features 120 and the space defined thereby may together be referred to herein as a “pump mount,” with at least one pump mount being arranged on plate 118 (i.e., at least as many pump mounts are provided as there are pumps 122).

The engagement features 120 of a given pump mount may be brackets configured to engage with a pump 122 by a friction fit, in some examples. In such examples, the brackets may protrude vertically from a face of the plate 118 and each group of brackets may at least partially bound lateral sides or edges of the corresponding space which is to receive the pump 122. The brackets further define an opening in a top side of the space through which a pump 122 can be inserted into the space by moving downward through the opening and between the brackets. The pump 122 may contact and slides against engagement surfaces of the brackets as it is inserted into the space, thus engaging with the engagement features 120.

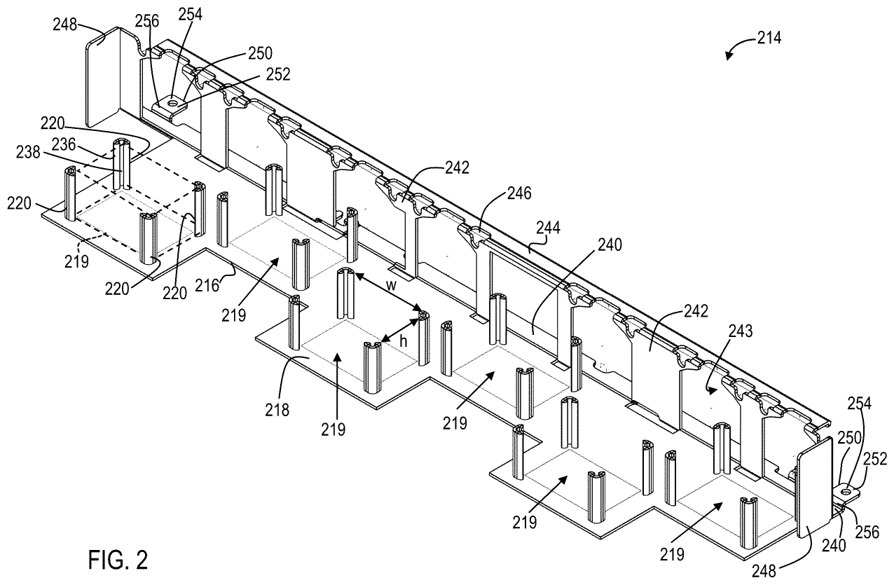

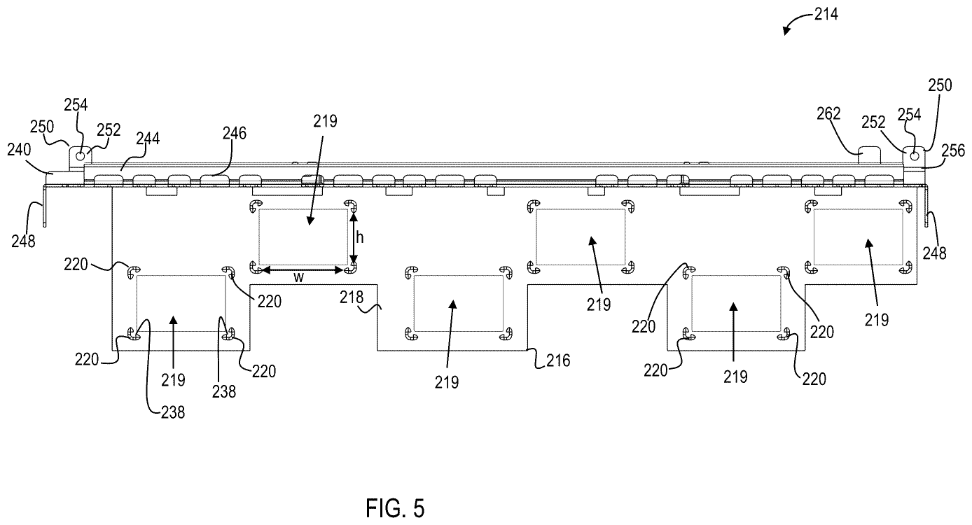

The group of brackets of a given pump mount may be arranged to abut the pump 122 on multiple side or edges thereof so as to constrain lateral motion of the pump 122 relative to the plate 118. In addition, the plate 118 may constrain downward motion of the pump 122. Thus, in some examples, the pump 122, when installed, may have just one degree of freedom of motion, namely upward motion away from the plate 118. In some examples, friction between the engagement surfaces and the pump 122 may resist such upward motion, thus holding the pump 122 in the pump mount. In other examples, snap-fit latching elements on the brackets may engage with a top side of the pumps to constrain upward motion of the pump 122. In some examples, the bracket may have an “L” or “C” shaped cross-sectional profile, as explained in more detail with respect to one example in FIGS. 2 and 5. However, examples are not so limited, and other varieties of engagement features 120 may be used. For example, engagement features 120 may include latches, snap-fit connectors, or features such as a post configured to be received within a corresponding feature on a pump.

Pump array assembly 112 may further include one or more pumps 122. As used herein, a pump refers to a mechanical device that uses suction or pressure to move liquids from one space to another. While only one pump 122 is shown in FIG. 1, examples are not so limited and other numbers of pumps 122 may be used. A maximum number of pumps 122 that may be included within pump array assembly 122 may be determined by a number of pump mounts disposed on plate 118. In many examples, multiple pumps 122 are provided and are arranged in array on the plate 118. The array may include various positional arrangements, including a straight line arrangement in which the pumps 122 are positioned at points on a line, which may extend parallel to a width dimension of the chassis 104 and perpendicular to the flow direction of the streams of liquid expelled by the pumps 122 (the width dimension of the chassis being perpendicular to the side walls of the chassis 104 and to a front-to-rear dimension of the chassis 104). As another example, the array may include a staggered arrangement in which the pump positions alternate between two (or more) parallel lines extending along the width dimension of the chassis. One example of a staggered arrangement is as follows: a pump 122 closest to a first side wall of the chassis 104 is positioned on a first line extending parallel to the width dimension of the chassis 104; the second closest pump 122 to the first side wall is positioned on a second line extending parallel to, but spaced apart from, the first line; the third closest pump 122 to the first side wall is positioned on the first line, the fourth closest pump to the first side wall is positioned on the second line, and so on in an alternating fashion for however many pumps 122 there are.

Pump 122 may include an intake 124 and an outlet 126 through which fluid, such as liquid coolant 132, may flow. Intake 124 may be an intake fluid coupling (e.g., a hose barb, a threaded fitting, etc.) which can couple with a tube or pipe, although examples are not so limited. Liquid 132 may flow into intake 124 and flow out outlet 126 such that the liquid 132 is directed over at least one electronic component 110. Outlet 126 may include a nozzle arranged to direct a stream of the liquid 132 over the electronic component 110. In some examples, the outlet 126 may include a fluid coupling similar to the intake 124, but in some examples this fluid coupling may be left uncoupled to a tube/pipe so that the fluid coupling acts similarly to a nozzle. The pump 122 may include an electric motor that drives rotation of an impeller which generates a pressure differential and causes the flow of liquid 132 from the intake 124 to the outlet 126. Pump 122 may also include a power cable 125 that supplies electrical power and/or data signals to the pump 122. In some examples, the power cable 125 may be connected to one of the fan power connectors 109 on system board 108. In such examples, instead of system board 108 supplying fan driving signals to a fan via fan power connectors 109, system board 108 may instead be configured to supply pump driving signals to the pump 122 via fan power connectors 109 to supply power and/or otherwise control operations of the pump 122.

In some examples where multiple pumps 122 are provided, an intake manifold 128 may be coupled to the intakes 124 of the pumps 122. As used herein, a manifold refers to a device which defines an interior volume that receives liquid via an input and distributes the liquid to multiple outputs. Intake manifold 128 may include a manifold body defining a volume through which coolant liquid 132 can flow. Intake manifold 128 may include an inlet 127 and outlets 129, which may be fluidically coupled with one another by the body of intake manifold 128. The outlets 129 of the intake manifold 128 may be fluidically coupled with the intakes 124 of the pumps 122. In some examples, the number of outlets 129 is equal to the number of pumps 122 and the intake 124 of each pump 122 is coupled with a corresponding one of the outlets 129. In other examples, the number of outlets 129 may be less than the number of pumps 122 such that some pumps 122 may share the same outlet 129—for example, a group of pumps may have their intakes 124 all fluidically coupled to the same outlet 129. Outlets 129 may be coupled directly to the inlets 124 or may be indirectly coupled to the inlets 124 via fluid conduits (tubes, pipes, etc.). In some examples, an outlet 129 may be screwed into a corresponding intake 124 or fluid conduit such that a threaded engagement between the outlet 129 and the intake 124 or fluid conduit maintains the connection between the intake manifold 128 and the pump 122. In other examples, an outlet 129 may engage with a corresponding intake 124 by a press fit or friction fit. Examples are not so limited and other connection means may be used.

System 100 may further include an immersion tank 130 including liquid coolant 132 held in a liquid-holding portion of the tank 130 to create a pool of liquid coolant 132. The liquid-holding portion of the tank 130 may be configured to receive information processing system 102 such that information processing system 102 is immersed in the pool of liquid coolant 132. As used herein, “immersed” means that at least the system board 108 is submerged in the liquid coolant 132. In some examples, the entirety of each information processing system 102 may be fully submerged. In other examples, a small portion of a system 102, such as a support bracket which supports the system, may protrude out of the liquid coolant 132. The immersion of system 102 in the liquid coolant 132 is shown by arrow 134.

The coolant 132 may be an electrically non-conducting material that is liquid at room temperatures, such as dielectric fluid. Immersion of information processing system 102 into liquid coolant 132 allows heat generated by electronic components 110 to be removed from the information processing system 102. More particularly, the coolant 132 absorbs heat from components of the system, via convection, and releases the heat externally from the system. In some examples, the coolant 132 may be a single-phase coolant, meaning it is engineered to absorb heat and circulate it through the immersion tank 130 while remaining substantially in a liquid phase. This circulation may include transferring the absorbed heat to a heat exchanger (not shown in FIG. 1) before being circulated back through the immersion tank 130, thus allowing liquid coolant 132 to be continually moved over the information processing system 102. In the single-phase system, substantially all of the heat transportation is achieved by the coolant 132 in liquid phase. While some coolant 132 may inevitably evaporate, this evaporation is incidental and not the primary mode of heat transport in a single-phase system. In other examples, the coolant 132 is a two-phase coolant, meaning it is engineered to transport heat by changing between liquid and vapor (gas) phases during operation of the device and to transport heat by way of this phase change. In such examples, the coolant 132 has a boiling point which is near a desired operating temperature of the electronic components 110, which means that the electronic components 110 can bring the coolant 132 to boiling during operation. This boiling absorbs heat from the components and allows the heat to be dissipated via interaction of coolant 132, in vapor form, with a heat sink or other heat dissipating structures (not shown).

When information processing system 102 is immersed in liquid coolant 132, pump 128 may be configured to move liquid coolant 132. More particularly, intake manifold 128 may draw liquid coolant 132 from the pool in the immersion tank 130 through inlet 127. Liquid coolant 132 may then move through the intake manifold 128 to exit at outlet 129. Because outlet 129 is fluidically connected with intake 124 of pump 122, the liquid coolant 132 moves through the intake 124 of pump 122 before exiting pump 122 at outlet 126. The outlet 126 may move liquid coolant 132 over at least one of the electronic components 110. More particularly, outlet 126 may be oriented to flow over selected electronic components 110. For example, outlet 126 may be positioned to allow liquid coolant 132 to flow over high-temperature components, such as a CPU or a memory, thus allowing additional liquid coolant 132 to be moved over components, increasing the cooling of these components.

Turning to FIGS. 2-7, an example mounting cage 214 is shown. Mounting cage 214 may be one implementation example of mounting cage 114 shown in and described with respect to FIG. 1 and may be used in a system such as system 100, described with respect to FIG. 1. Mounting cage 214 thus comprises components which correspond to (i.e., are implementation examples of) components of the mounting cage 114, and the correspondence between such components is indicated herein by the components having reference numbers with the same last two digits, such as 120 and 220. Aspects of the mounting cage 114 and its components described above may also be applicable to the mounting cage 214 and its corresponding components, but the mounting cage 114 and its components are not limited to the mounting cage 214 and its components, which are just one example of how the mounting cage 114 may be implemented. In some instances, aspects of the mounting cage 114 already described above, which are also applicable to the mounting cage 214, are not described below to avoid duplicative description.

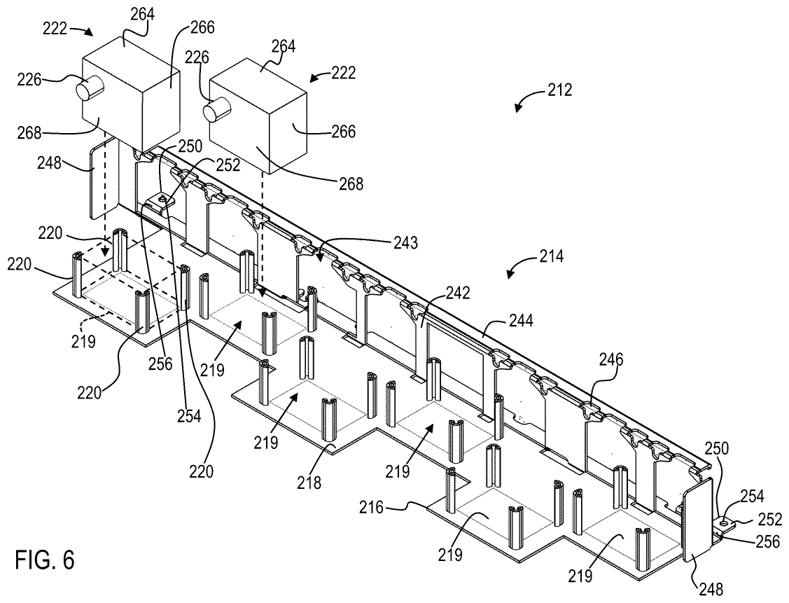

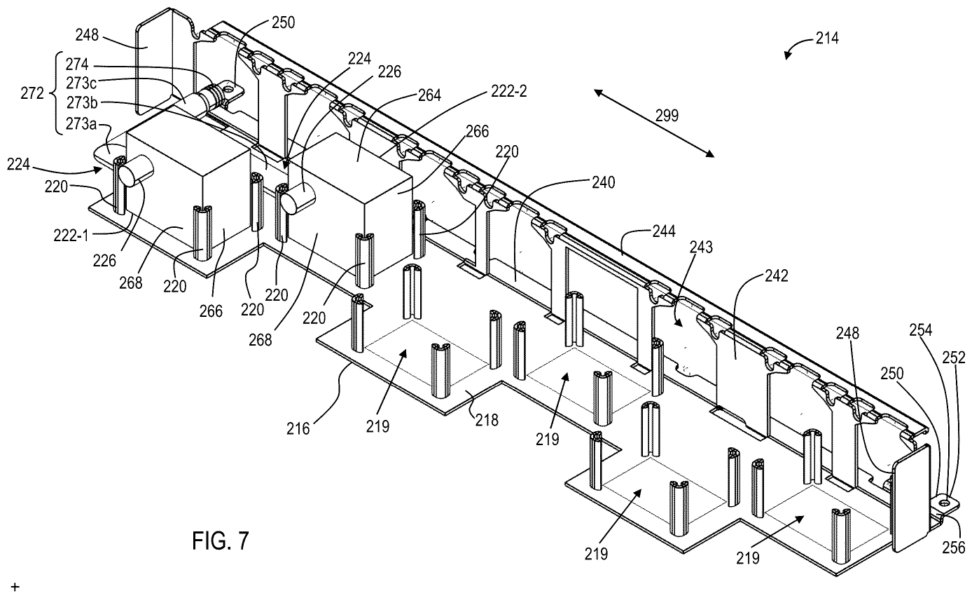

Mounting cage 214 includes a base 216. Base 216 includes a plate 218 and a plurality of engagement features 220. While only a subset of engagement features 220 may be labeled, it should be understood that the non-labeled engagement features have similar features to labeled engagement features 202. Engagement features 220 comprise a bracket formed by a wall 236 with a gap 238 defined by the edges of the wall 236, with the gap 238 bounded by the wall 236. More particularly, the bracket may have an “L” or “C” shaped cross-sectional profile, as described previously, such that gap 238 may correspond to the opening in the “L” or “C”. Gap 238 may be sized to slidably receive a pump, such as pump 222 as shown in FIGS. 6 and 7, and retain the pump 222 within an individual engagement feature 220.

Each engagement feature 220 is coupled to the plate 218 at a first end and extends vertically from the plate 218. A plurality of engagement features 220 can be arranged on the plate 218 to accommodate a pump. As shown in FIGS. 2 and 5-7, a set of four engagement features 220 is arranged on plate 218 to define an open, rectangular space 219 having a height h and a width w. Each of the individual engagement features 220 is coupled to the plate 218 at one corner of the rectangular space 219, such that engagement features 220 are arranged at the corners of the space 219. Space 219 and its corresponding set of engagement features 220 together define a pump mount, with the pump mount being configured to receive, retain, and support a pump, such as pump 222, shown in FIGS. 6-7, with respect to base 216. In this example, there are six pump mounts, thus allowing for six pumps to be mounted to the mounting cage 214 (although not all of pump mounts necessarily have to be populated with pumps in any given implementation). Other examples of a mounting cage (not illustrated) may be similar to mounting cage 214 but may have more or fewer pump mounts. In this example, the pump mounts are distributed across a longitudinal dimension 299 of the cage 214, which corresponds to a chassis width dimension when the cage 214 is installed in a chassis. In this example, the pump mounts are arranged in a staggered pattern. The staggered arrangement can allow for pumps whose inlets extend along the longitudinal dimension 299 of the cage 214 to be positioned close to one another with their inlets extending either behind or in front of the adjacent pumps. If such pumps were instead arranged in one straight line, then they may need to be spaced farther apart from one another to avoid having the inlet of one pump interfere with an adjacent pump. In other examples of mounting cage (not illustrated), pump mounts can be arranged in a different pattern, such as all in one straight line, a different staggered pattern, or in any other desired arrangement.

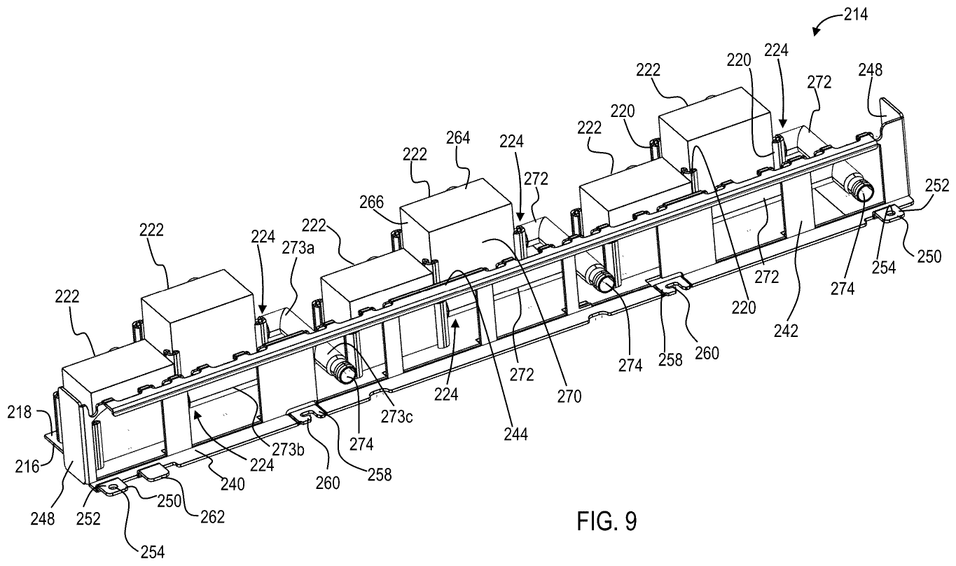

More particularly, as shown in FIGS. 6-7, each individual pump 222 includes a top wall 264, a bottom wall (not pictured), offset from and parallel to top 264, and side walls 266. Pump 222 further includes a front wall 268 and a rear wall 270 (shown in FIGS. 9-11 and discussed further with respect thereto) disposed offset form and parallel to front wall 268. One side wall 266 is shown in FIGS. 6-7; however, it should be understood that a second side wall is disposed opposite and, like side wall 266 shown in FIGS. 6-7, extends between and connects top wall 264 with front wall 268, as well as with the bottom wall and the rear wall. When a pump 222 is being installed into a pump mount, as shown in FIG. 6, the pump 222 is aligned with a particular rectangular space 219 and its corresponding engagement features 220. Because engagement features 220 are a bracket having a gap 238 bounded by walls 236, the edges where the side walls 266, the front wall 268, and the rear wall 270, respectively, meet can be inserted into the space of gap 238 and be slid through the length of the engagement features 220 until the pump 222 is fully received within the pump mount and the bottom wall of the pump 222 rests on and is supported by plate 218 in the defined rectangular space 219. As shown in FIG. 7, each pump 222, when installed, is retained by engagement features 220. More particularly, inserting the edges of pump 222 into the gaps 238 of the engagement features 220 deflects the walls 236 of the engagement features 220, allowing pump 222 to move through gap 238. Once pump 222 is in an installed location, as shown in FIG. 7, walls 236 contact and grip the edges of pump 222, thereby retaining the pump 222 on plate 218.

In this example, the cage 214 further includes a wall 242 extending vertically from base 216 to provide additional structure and stability to mounting cage 214. Wall 242 includes a plurality of cutout portions 243 which extend through a thickness of the wall 242. Cutout portions 243 allow cables, such as power cables coupled to pumps 222, to be routed through mounting cage 214 while maintaining an open structure to allow liquid coolant to flow through and around the mounting cage 214. An upper ledge 244 extends perpendicularly from wall 242 and includes openings 246 adjacent the cutout portions 243. Openings 246 similarly permit liquid coolant to flow through and around the upper ledge 244.

A lower ledge 240 extends from the wall 242 parallel to and offset from upper ledge 244. Lower ledge 240 is substantially parallel to and coupled with base 216, such that lower ledge 240 extends away from plate 218 of base 216. Lower ledge 240 may include attachment features which allow mounting cage 214 to be coupled to a chassis. As shown in FIGS. 2 and 4-5, in particular, one such attachment feature is attachment tabs 250. Attachment tabs 250 extend perpendicularly from lower ledge 240.

Attachment tabs 250 include a horizontal portion 252 that is parallel to lower ledge 240. An aperture 254 is formed within horizontal portion 252, with aperture 254 being sized to receive a fastener, such as a screw or a peg. Horizontal portion 252 of attachment tab 250 is coupled to lower ledge 240 at vertical portion 256, with vertical portion 256 extending between and connecting an edge of lower ledge 240 with an edge of horizontal portion 252 of attachment tab 250. In this way, attachment tabs 250 are both horizontally and vertically offset from lower ledge 240. Although two attachment tabs 250 are shown in FIGS. 2 and 4-5, examples are not so limited, and more or fewer attachment tabs may be used.

In use, attachment tabs 250, and particularly apertures 254, are aligned with corresponding openings on the chassis, corresponding to fan cage attachment points such as fan cage attachment points 110, discussed with respect to FIG. 1. Once attachment tabs 250 are in the correct position, fasteners, such as screws, pegs, or the like, may be passed through apertures 254 and the corresponding attachment points on the chassis, thus coupling mounting cage 214 to the chassis.

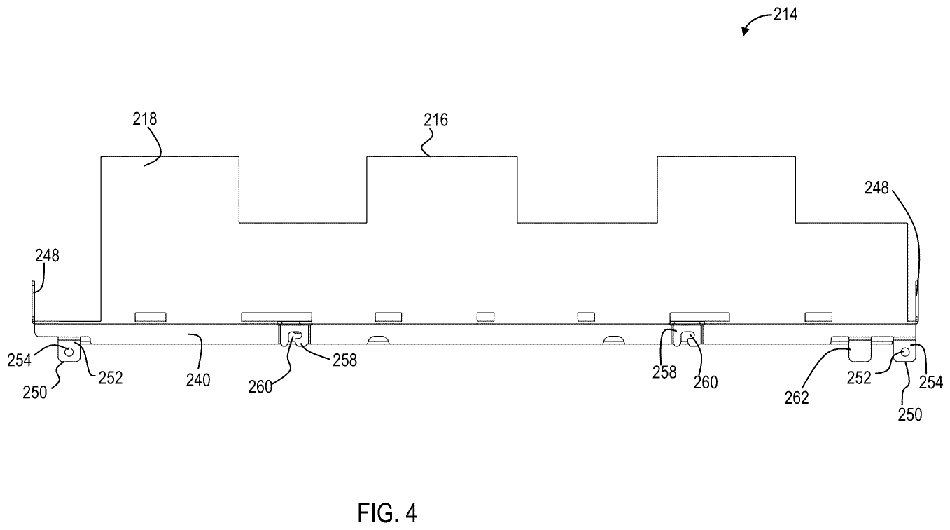

In addition, lower ledge 240 may include locating features 258, as shown in FIG. 4. Locating features 258 include a cutout 260 which selectively engage with corresponding features, such as pins, on the chassis and/or on the system board. More particularly, pins slide into cutout 260 to maintain mounting cage 214 in a desired position. As shown in FIG. 4, lower ledge 240 may include both locating features 258 and attachment tabs 250. Thus, during installation of mounting cage 214, the mounting cage 214 can first be located on the system board at the locating features 258 before being coupled with the chassis at attachment tabs 250. A grasping tab 262 may extend from lower ledge 240 and may provide an additional point of contact at which a user can manipulate the mounting cage 214.

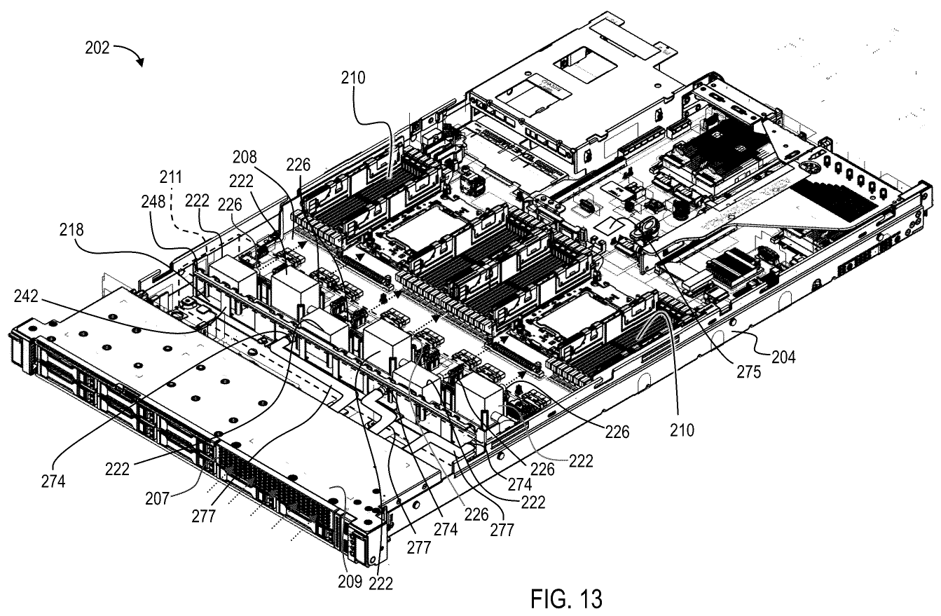

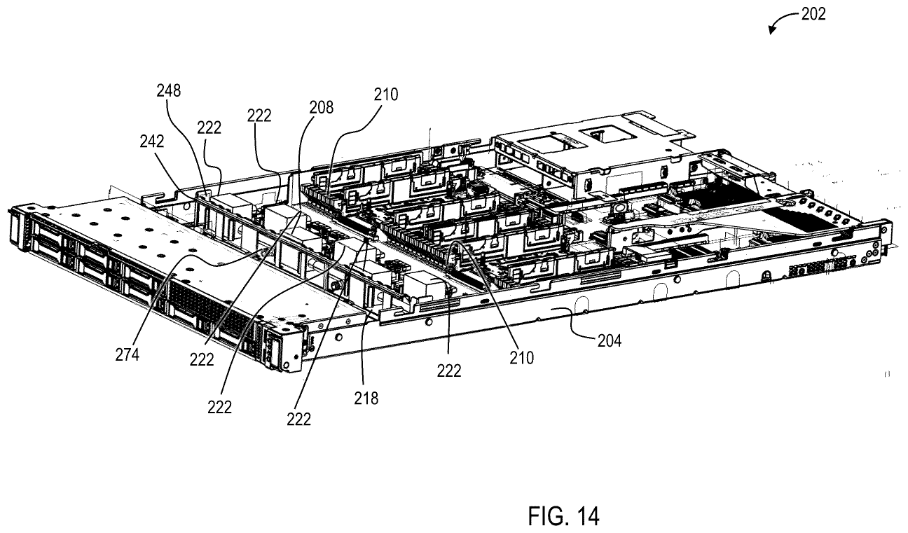

Returning to FIG. 2 in particular, a pair of side walls 248 extend perpendicularly from wall 242, with side walls 248 being separated by the length of wall 242. When mounting cage 214 is installed within a chassis, each of side walls 248 contacts a corresponding side of the chassis, providing an additional point of contact between the mounting cage 214 and the chassis. This configuration is discussed further with respect to FIGS. 13 and 14.

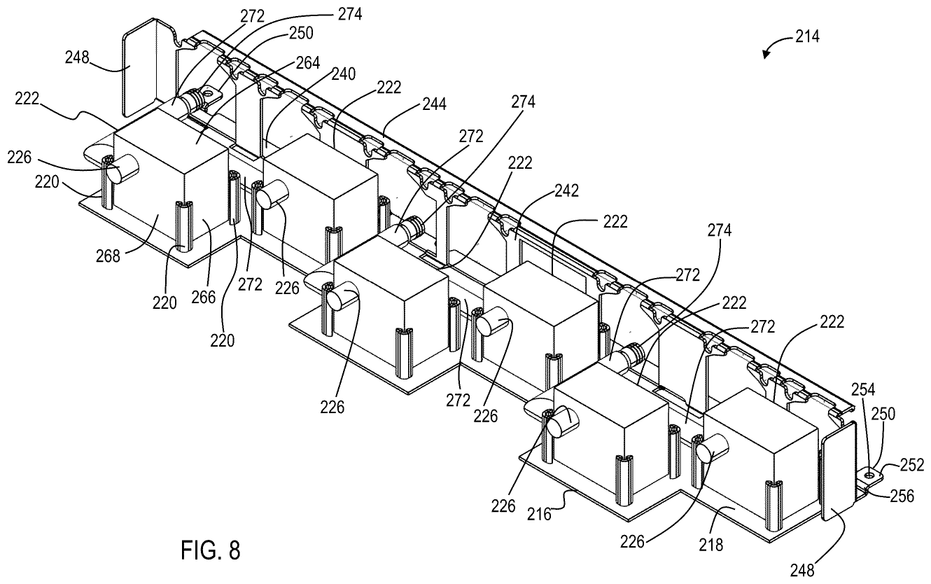

Turning specifically to FIGS. 6-9, a pump array assembly 212 comprising the mounting cage 214 and pumps 222 is shown in various states of assembly. As explained above, mounting cage 214 is configured to receive at least one pump 222. Two pumps are shown in FIGS. 6 and 7 in uninstalled and installed states, and six pumps are shown in installed state in FIGS. 8 and 9, however, examples are not so limited, and more or fewer pumps may be installed. As shown in FIG. 6, each individual pump 222 is aligned with a pump mount and moved towards base 216. FIGS. 6 and 7 show pumps 222 installed such that the front wall 268 faces opposite the wall 242 of mounting cage 214. Each pump 222 includes an outlet 226 on the front wall 268; thus, in the installed position shown in FIG. 7, outlet 226 also faces away from wall 242. In addition, each pump 222 includes an intake. The intakes are not visible in FIGS. 6-11 because they are covered by liquid conduits 272 which are couple thereto, as explained below. However, the general locations of the intakes are indicated by the arrows labeled 224 in FIGS. 7 and 9.

In some examples, liquid conduits 272 may be installed to fluidically couple two or more pumps 222 to a common inlet port 274. In the examples illustrated in FIGS. 7-11, liquid conduits 272 are coupled to the intakes of the pumps 222. Each of the illustrated liquid conduits 272 has a “Y” or “T” configuration, with a single inlet tube 273c having a common inlet port 274 at one end of the conduit 272 and at least two outlet tubes 273a and 273b at the other end of the conduit 272, with the inlet and outlet tubes 273c, 273a, and 273b being fluidically coupled together (e.g., via a T-coupling). In some examples, additional outlet tubes may be included, with the additional outlet tubes also configured to be coupled to inlet tube 273c. The outlet tubes 273a and 273b are coupled to the intakes of two of the pumps 222. Thus, the intakes of a pair of the pumps 222 are fluidically coupled to the same common inlet port 274. For example, as shown in FIG. 7, a first outlet tube 273a of a liquid conduit 272 is coupled to the intake of a first pump 222-1 and a second outlet tube 273b is coupled to the intake of a second pump 222-2, these tubes 273a and 273b then join together and join with inlet tube 273c via a T-junction, and inlet tube 273c then terminates in the common inlet port 274 extending away from pump 222 towards a cutout portion 243 in wall 242. In such examples, the intakes of each of the pumps 222 are fluidically coupled by the liquid conduit 272 to the common inlet port 274. This allows a single inlet, namely common inlet port 274, to direct fluid through the fluidically coupled pumps 222.

As shown in FIGS. 8 and 9, multiple pumps 222 can be installed on plate 218 as part of mounting cage 214, with FIGS. 8 and 9 showing six pumps 222 installed. Each pump 222 is installed in a pump mount, as shown in FIG. 2. That is, each pump 222 is installed within a rectangular space 219 and is held in place by a corresponding set of engagement features 220. Each pump 222 has an outlet 226 formed as part of the front wall 268. In the installed pumps 222 shown in FIGS. 8 and 9, each outlet 226 is facing away from the wall 242; however, examples are not so limited and pumps 222 may be oriented in different directions with respect to one another.

In systems where more than two pumps 222 are installed, multiple liquid conduits 272 are installed to fluidically couple two pumps 222 at a common inlet port 274. As with the pumps 222 shown in FIG. 7, the common inlet port 274 directs fluid through the fluidically coupled pumps 222.

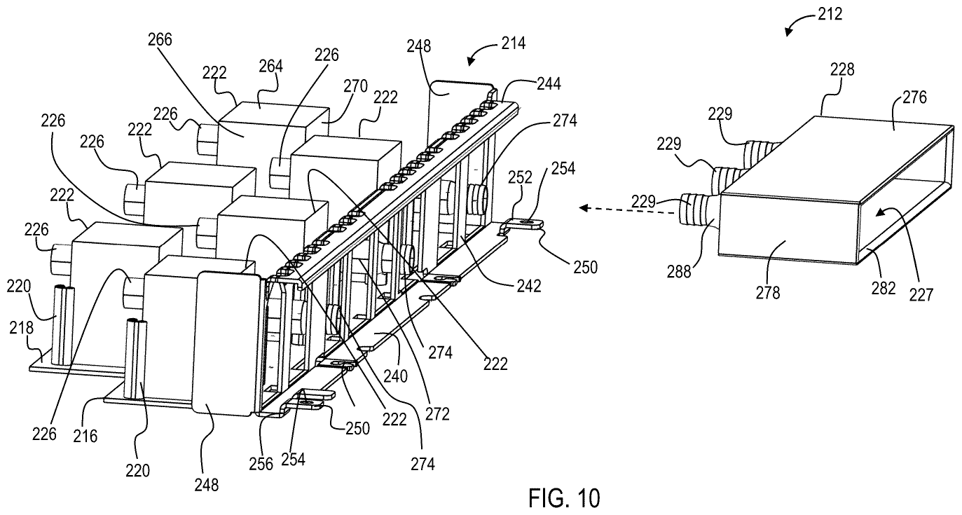

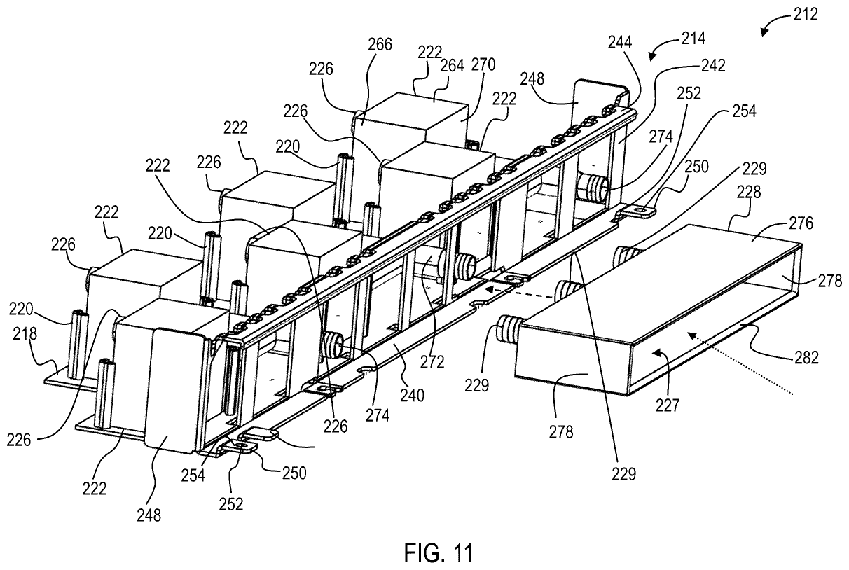

In some instances, the pump array assembly 212 may also include an intake manifold 228, as shown FIGS. 10-12. As shown in FIGS. 10 and 11, the mounting cage 214 has six pumps 222 installed, with each pump 222 being held in place by engagement features 220. Intake manifold 228 is shown separated from the pumps 222.

Intake manifold 228 comprises a top wall 276, a bottom wall 280, and a pair of side walls 278 connecting the top wall 276 and the bottom wall 280 to form an open rectangular prism (i.e., a box). A front wall 284 closes one side of the rectangular prism. Inlet 227 is defined by the other opening formed by the top wall 276, bottom wall 280, and side walls 278, allowing liquid coolant to flow into the intake manifold 228. The inlet 227 is bounded by a ramped surface 282, with the ramped surface 282 extending around the perimeter created by the top wall 276, bottom wall 280, and side walls 278. In some examples, the ramped surface 282 facilitates insertion of another component, such as another pump, into the inlet 227 of the intake manifold 228.

Outlets 229 extend from front wall 284, opposite inlet 227, such that liquid flowing through the intake manifold 228 enters inlet 227 and exits via outlets 229. Although three outlets 229 are shown, examples are not so limited and more or fewer outlets 229 may be used. The outlets 229 are spaced from the front wall 284 by shoulders 288. In some examples, the shoulders 288 provide narrowing between the open space of the inlet 227 and the outlets 229. This can aid in increasing the speed with which the liquid coolant exits the intake manifold 228 at outlets 229.

Intake manifold 228 couples with pumps 222 installed on a mounting cage 214. More particularly, outlets 229 of intake manifold 228 physically engage with common inlets ports 274 to fluidically couple the intake manifold 228 with the pumps 222. This allows fluid to move through intake manifold 228 into the pumps 222, where it is then directed over electronic components.

FIGS. 13 and 14 are perspective views of an information processing system 202 in which the pump array assembly 212, including the mounting cage 214, pumps 222, and intake manifold 228, described above may be used. Information processing system 202 includes a chassis 204 supporting a system board 208. System board 208 includes a plurality of electronic components 210 coupled thereto. While two electronic components 210 are shown in FIGS. 13 and 14, examples are not so limited and more or fewer electronic components 210 may be present. Electronic components 210 may be a processor such as a CPU, a memory, or any other core components. Chassis 204 may further include a fan region 211 in which fans would be installed in an air cooled configuration. In FIGS. 13 and 14, the system is in an immersion cooling configuration, and therefore the fans are removed and a fan cage is not present, allowing portions of the pump array assembly 212 to be installed in the fan region 211.

More particularly, the mounting cage 214 is installed with the plate 218 substantially parallel to system board 208, with side walls 248 adjacent to a side wall of chassis 208. Additionally, although not shown in FIGS. 13 and 14, attachment features, such as attachment tabs 250 and/or locating features 258, couple mounting cage 214, and thus pump array assembly 212, to chassis 204.

A plurality of pumps 222 are installed within mounting cage 214 such that, in an installed position of pump array assembly 212 at chassis 204, fluid outlets 226 of the pumps 222 face and direct streams of liquid toward electronic components 210 (flows of liquid coolant are indicated in FIG. 13 by dash-lined arrows). The pumps 22 are paired, and each pair of the pumps 222 is coupled to the same liquid conduit 272 which includes a common fluid inlet 274, such that the intakes 226 of the two pumps 222 are fluidically coupled to one another, as described above. The common fluid inlets 274 of the various liquid conduits 272 are then each coupled to a corresponding liquid conduit 277, each of which is in turn coupled to a corresponding one of the outlets 229 of the intake manifold 229 (not shown in FIGS. 13 and 14). Thus, liquid enters the manifold 229, is distributed from the manifold 229 to the liquid conduits 227, flows from each liquid conduit 227 to a corresponding liquid conduit 272, flows from each liquid conduit 272 to a corresponding pair of the pumps 222, and then the pumps 222 eject the liquid coolant out the outlets in streams which are directed towards and/or over the electronic components 210.

In this example, intake manifold 229 is disposed within a bay 207 of a drive cage 209 at a front panel of the chassis 204, and thus the intake manifold 229 is not visible in the views of FIGS. 13 and 14. The intake manifold 229 is provided in the bay 207 in lieu of drives or other modules which might otherwise have occupied the bay 207. An inlet 227 of the manifold 229 may be positioned behind and facing towards a perforated front panel of the bay 207 and the intake manifold 229 may draw in liquid from outside the chassis 304 through this perforated front panel. Accordingly, the liquid drawn into the manifold 229 in this fashion will not yet have passed over any of the electronic devices in the system 202, and thus will not have been pre-heated by those devices. On the other hand, the liquid immediately surrounding the pumps 222 may have passed over various electronic devices, such as storage drives in the drive cage 209 or other electronic components (not illustrated) positioned between the drive cage 209 and the fan region 211, before reaching the region around the pumps 222, and therefore the liquid around the pumps 222 may be warmer than the liquid drawn in by the manifold 229. Thus, using the manifold 229 to supply liquid to the pumps 222 may allow for the liquid streams ejected by the pumps to be cooler than they otherwise would have been if the pumps 222 were to instead draw in liquid from their immediate vicinity.

Pumps 222 are further configured to be electronically connected to the system board 208 at a power supply connector on the system board. In some examples, pumps 222 is configured to couple to a fan power supply connector, although examples are not so limited.

In addition, pumps 222 are electrically coupled to a control system 275 located on the system board 208. The control system 275 comprises a temperature sensor disposed on or in at least one of electronic components 210 to monitor the operating temperature of the electronic component 210. The control system 275 further comprises a pump speed control interface, which is communicably coupled with the temperature sensor. The pump speed control interface is configured to dynamically control at least one of the pumps 222. More particularly, the pump speed control interface is configured to alter a speed of at least one of the pumps 222, thus increasing or decreasing the amount of liquid coolant moved through the pump 222. The pump speed may be altered by the pump speed control interface in response to a temperature, as measured at the temperature sensor, reaching a threshold temperature. That is, the speed of pumps 222 may increase when an electronic component 210 approaches a threshold temperature. This allows cooling liquid to be directed over those electronic components 210 that require more cooling. In some examples, the pump speed control interface may be a baseboard management controller (BMC), although examples are not so limited.

When information processing system 202 is immersed in an immersion tank having a pool of liquid coolant, such as immersion tank 130 having liquid coolant 132, described with respect to FIG. 1, the pump helps direct additional liquid coolant over the electronic components 210 via the fluid outlets. Thus, even when information processing system 202 is immersed in the liquid coolant to provide system cooling, certain electronic components 210 are able to receive additional cooling, allowing information processing system 202 to remain at an operating temperature that is unlikely to cause heat-related damage to the system components.

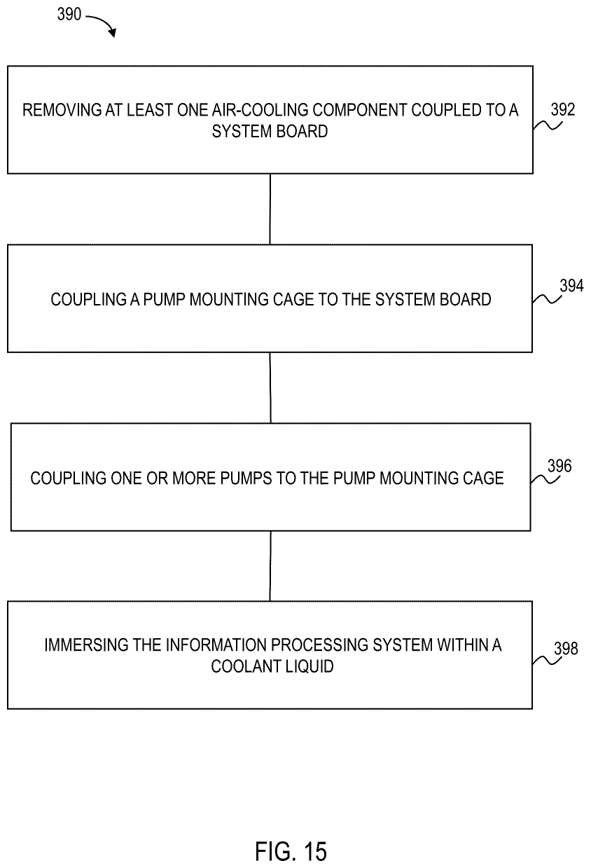

FIG. 15 is a method 390 for adapting a system for immersion cooling. At 392, method 390 includes removing at least one air-cooling component coupled to a system board. The air-cooling component may be a fan cage, a fan, or any other component used in an air-cooled system. Removal of the at least one air-cooling component creates an available volume on the system board. That is, by removing at least one air-cooled component, the system board has an empty space which used to be occupied by the at least one air-cooled component.

At 394, method 390 includes coupling a pump mounting cage to a system board. More particularly, coupling a pump mounting cage to a chassis includes engaging attachment features on the pump mounting cage with corresponding features on the chassis. The features on the chassis may correspond to an attachment feature of the air-cooling component removed at 362, allowing the engagement features on the pump mounting cage to be attached in lieu of the removed air-cooling component. For example, as described with respect to FIG. 1 in particular, the attachment feature on the chassis may be a fan cage attachment feature, although examples are not so limited. This attachment feature may engage with an engagement feature, such as the engagement tabs described with respect to FIGS. 2-9, on the mounting cage. When the mounting cage is coupled to the chassis, the mounting cage is disposed within the available volume on the system board. Said differently, mounting cage is configured to occupy the space originally occupied by the at least one air-cooling component, which was removed at 362.

At 396, method 390 includes coupling one or more pumps to the pump mounting cage. Coupling one or more pumps to the pump mounting cage comprises engaging each pump of the one or more pumps with pump receiving features on the pump mounting cage. These pump receiving features may be engagement features, such as those discussed with respect to FIGS. 1-9. Once a pump is engaged with the pump receiving feature, the pump can be electrically coupled to the system board. The pump may be electrically coupled at a power source made available by the removal of the at least one air-cooling component at 392. For example, if the air-cooling component removed at 392 is a fan, a pump may be electrically coupled to the system board in lieu of, but at the same location as, the removed fan.

Coupling one or more pumps to the pump mounting cage at 396 may further include coupling an intake of the one or more pumps with a corresponding output of an intake manifold. As described with respect to FIGS. 10-12, the intake manifold may be selectively coupled with an intake of the one or more pumps to direct fluid, such as a liquid coolant, through the pumps.

At 398, method 390 includes immersing the information processing system within a coolant liquid. More particularly, immersing the information processing system within a coolant liquid at 398 comprises immersing at least a portion of the system board including the immersion cooling adapter within the coolant liquid. This immersion allows the pump to move coolant liquid to the manifold, providing cooling for components on the system board. In some examples, the coolant liquid is a dielectric liquid, although examples are not so limited.

It is to be understood that both the general description and the detailed description provide example implementations that are explanatory in nature and are intended to provide an understanding of the present disclosure without limiting the scope of the present disclosure. Other examples in accordance with the present disclosure will be apparent to those skilled in the art based on consideration of the disclosure herein. For example, various mechanical, compositional, structural, electronic, and operational changes may be made to the disclosed examples without departing from the scope of this disclosure, including for example the addition, removal, alteration, substitution, or rearrangement of elements of the disclosed examples, as would be apparent to one skilled in the art in consideration of the present disclosure. Moreover, it will be apparent to those skilled in the art that certain features or aspects of the present teachings may be utilized independently (even if they are disclosed together in some examples) or may be utilized together (even if disclosed in separate examples), whenever practical. In some instances, well-known circuits, structures, and techniques have not been shown or described in detail in order not to obscure the examples. Thus, the following claims are intended to be given their fullest breadth, including equivalents, under the applicable law, without being limited to the examples disclosed herein.

References herein to examples, implementations, or other similar references should be understood as referring to prophetic or hypothetical examples, rather than to devices/systems that have been actually produced, unless explicitly indicated otherwise. Similarly, references to qualities or characteristics of examples should be understood as representing the educated estimates or expectations of the inventors based on their understanding of the relevant principles involved, application of theory and/or modeling, and/or past experiences, rather than as being representations of the actual qualities or characteristics of an actually produced device/system or the empirical results of tests actually carried out, unless explicitly indicated otherwise.

Further, spatial, positional, and relational terminology used herein is chosen to aid the reader in understanding examples of the invention but is not intended to limit the invention to a particular reference frame, orientation, or positional relationship. For example, spatial, positional, and relational terms such as “up”, “down”, “lateral”, “beneath”, “below”, “lower”, “above”, “upper”, “proximal”, “distal”, and the like may be used herein to describe directions or to describe one element's or feature's spatial relationship to another element or feature as illustrated in the figures. These spatial terms are used relative to reference frames in the figures and are not limited to a particular reference frame in the real world. Furthermore, if a different reference frame is considered than the one illustrated in the figures, then the spatial terms used herein may need to be interpreted differently in that different reference frame. Moreover, the poses of items illustrated in the figure are chosen for convenience of illustration and description, but in an implementation in practice the items may be posed differently.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition. Moreover, unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

What is claimed is:

1. An information processing system, comprising:
a system board comprising electronic components;
a chassis supporting the system board and comprising fan cage attachment points configured to receive a fan cage;
a pump array assembly, comprising:
a mounting cage configured to couple to the chassis at the fan cage attachment points; and
one or more pumps coupled to the mounting cage, wherein each of the pumps:
comprises an intake and an outlet; and
is configured to, in a state of the information processing system immersed in a pool of liquid coolant in an immersion cooling tank, draw a flow of the liquid coolant from the pool through the intake and eject the flow through the outlet back into the pool as at least one output stream directed over at least one of the electronic components.

2. The system of claim 1, further comprising an intake manifold fluidically coupled to the respective intakes of the pumps.

3. The system of claim 1, further comprising a control system electrically coupled to the pumps, the control system further comprising:
a temperature sensor disposed on or in one of the electronic components; and
a pump speed control interface communicably coupled to the temperature sensor, wherein the pump speed control interface dynamically controls the one or more pumps.

4. The system of claim 3, wherein the pump speed control interface alters a speed of at least one of the pumps in response to a temperature measured at the temperature sensor reaching a threshold temperature.

5. The system of claim 3, wherein the pump speed control interface is a baseboard management controller (BMC).

6. The system of claim 1, wherein the mounting cage comprises a base which comprises:
a plate to support the pumps; and
one or more pump mounts arranged on the plate, each pump mount comprising a space in which to receive one of the pumps and a plurality of engagement features coupled to the base and configured to hold the pump received in the space.

7. The system of claim 6, wherein the plurality of engagement features comprises a plurality of brackets configured to slidably receive the at least one pump and retain the at least one pump by a friction fit.

8. The system of claim 7, wherein:
the plurality of brackets comprises four brackets arranged at corners of a rectangle on the plate; and
each bracket of the plurality of brackets is coupled to the plate at a first end and extends vertically from the plate.

9. The system of claim 1, wherein:
the one or more pumps comprises a first pump and a second pump; and
the intakes of the first and second pumps are both fluidically coupled by liquid conduits to a common inlet port.

10. The system of claim 1, wherein the at least one pump is electrically coupled to a fan power connector in lieu of a fan.

11. The system of claim 1, wherein:
the pump array assembly is disposed in a fan region of the chassis, the fan region of the chassis configured to receive the fan cage and fans; and
the fan region of the chassis is located between the system board and a front panel or a rear panel of the chassis.

12. A pump array assembly, comprising:
a pump mounting cage, comprising:
a base defining a plurality of locations to receive and support one or more pumps, the base further configured to engage with a chassis of an information processing system; and
a plurality of engagement features to retain the one or more pumps with respect to the base in an installed state of the one or more pumps in the pump mounting cage; and
an intake manifold fluidically coupled to the one or more pumps at an intake valve of the one or more pumps.

13. The pump array assembly of claim 12, wherein the base further comprises a pair of walls extending vertically perpendicular to the base and configured to engage with the chassis via a friction fit between the pair of walls and corresponding side walls of the chassis to couple the pump mounting cage to the chassis.

14. The pump array assembly of claim 12, wherein the base further comprises a plurality of screw attachment points extending parallel from the base and configured to engage with corresponding screw attachment points on the chassis to couple the pump mounting cage to the chassis.

15. The pump array assembly of claim 12, wherein:
the intake manifold further comprises a manifold intake and a manifold output; and
the manifold output is fluidically coupled to the intake valve of the pump by a tube extending between the manifold output and the pump intake valve.

16. A method for adapting an information processing system for immersion cooling, comprising:
removing at least one air-cooling component coupled to a system board, wherein removing at least one air-cooling component creates an available volume on the system board;
coupling a pump mounting cage to a chassis, wherein the pump mounting cage is coupled to the chassis within the available volume on the system board;
coupling one or more pumps to the pump mounting cage; and
immersing the information processing system within a coolant liquid.

17. The method of claim 16, wherein coupling a pump mounting cage to the chassis comprises engaging attachment features on the pump mounting cage with the chassis.

18. The method of claim 16, wherein coupling one or more pumps to the pump mounting cage further comprises:
engaging the one or more pumps with pump receiving features on the pump mounting cage; and
electrically coupling the one or more pumps to the system board.

19. The method of claim 18, wherein electrically coupling the one or more pumps to the chassis comprises electrically coupling the one or more pumps to a power source previously used by the at least one air-cooling component.

20. The method of claim 18, wherein coupling one or more pumps to the pump mounting cage further comprises coupling an intake of the one or more pumps with a corresponding output of an intake manifold.
